(19) United States
(12) Patent Application Publication
(10) Pub. No.: US 2026/0310868 A1
(43) Pub. Date: Oct. 8, 2026

(54) COLLABORATIVE DEBUGGING ACROSS FIRMWARE AND HARDWARE

(71) Applicant: International Business Machines Corporation, Armonk, NY (US)

(72) Inventors: Pretty Mariam Jacob, Bangalore (IN); Arun Joseph, Whitefield (IN); Rohan Sharma, Bangalore (IN); Carsten Otte, Stuttgart (DE); Sajay Mathew Karottukottarathil Baby, Bangalore (IN)

(21) Appl. No.: 19/171,211

(22) Filed: Apr. 5, 2025

(51) Int. Cl. G06F 30/3308; G06F 11/362; G06F 30/3323

(52) U.S. Cl. CPC G06F 30/3308; G06F 11/3636; G06F 30/3323

(57) ABSTRACT

A computer-implemented method, system, and computer program product for testing and debugging firmware and hardware in a collaborative manner. A collaborative debug platform is utilized in which a snapshot of an architected state produced by a firmware simulator after executing firmware on the firmware simulator is captured. Furthermore, a hardware simulation model is initialized using the snapshot of the architected state. After such an initialization, one or more cycles of hardware execution are simulated on the hardware simulation model. Debugging on hardware facilities of interest (e.g., registers, memory, caches, signals, etc.) on the hardware simulation model is then performed. A snapshot and/or traces of states of the hardware facilities of interest produced by the hardware simulation model after performing the debugging are captured. Such a snapshot and/or traces of states of the hardware facilities of interest are then utilized in executing the firmware on the firmware simulator.

### TECHNICAL FIELD

The present disclosure relates generally to testing and debugging in the context of firmware and hardware, and more particularly to collaborative debugging across firmware and hardware.

### BACKGROUND

In the context of firmware and hardware, “testing” refers to verifying that the firmware (e.g., the software embedded within a hardware device) or hardware (e.g., hardware device) functions correctly by running it through various scenarios to identify potential issues while “debugging” refers to the process of pinpointing and fixing specific errors or bugs found during testing.

### SUMMARY

In one embodiment of the present disclosure, a computer-implemented method for testing and debugging firmware and hardware comprises executing firmware on a firmware simulator. The method further comprises capturing a snapshot of an architected state produced by the firmware simulator after executing the firmware on the firmware simulator. The method additionally comprises initializing a hardware simulation model using the snapshot of the architected state. Furthermore, the method comprises simulating one or more cycles of hardware execution on the hardware simulation model after the initialization of the hardware simulation model. Additionally, the method comprises performing debugging of hardware facilities of interest on the hardware simulation model after the simulation. In addition, the method comprises capturing one or more of a snapshot and traces of states of the hardware facilities of interest produced by the hardware simulation model after performing the debugging. The method further comprises executing the firmware on the firmware simulator using the one or more of the snapshot and the traces of states of the hardware facilities of interest.

Other forms of the embodiment of the computer-implemented method described above are in a system and in a computer program product.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present disclosure can be obtained when the following detailed description is considered in conjunction with the following drawings, in which:

FIG. 1 illustrates an embodiment of the present disclosure of a computing environment for practicing the principles of the present disclosure;

FIG. 2 illustrates the stages performed in testing and debugging firmware and hardware in a collaborative manner in accordance with an embodiment of the present disclosure;

FIG. 3 is a diagram of the software components used by the computer to test and debug firmware and hardware in a collaborative manner in accordance with an embodiment of the present disclosure; and

FIGS. 4A-4B are a flowchart of a method for testing and debugging firmware and hardware in a collaborative manner in accordance with an embodiment of the present disclosure.

### DETAILED DESCRIPTION

As stated above, in the context of firmware and hardware, “testing” refers to verifying that the firmware (e.g., the software embedded within a hardware device) or hardware (e.g., hardware device) functions correctly by running it through various scenarios to identify potential issues while “debugging” refers to the process of pinpointing and fixing specific errors or bugs found during testing.

Such testing and debugging may involve pre-silicon system simulation, which refers to the process of testing and verifying the functionality of a complete electronic system design using a computer simulation before the actual physical hardware (“silicon”) is manufactured. For example, pre-silicon system simulation is performed to identify and fix potential design flaws in a complex system, such as an integrated circuit (IC) system, before the physical chip is manufactured allowing for earlier bug detection, faster development cycles, and reduced costs by mitigating the need for costly silicon re-spins later in the process. By simulating the system behavior before silicon is fabricated, design issues can be identified and corrected early in the design process, preventing potential problems that could arise once the chip is physically built. That is, identifying and fixing bugs early in the design process significantly reduces the overall development time by minimizing the need for post-silicon debugging and rework.

However, testing and verifying the functionality of a complete electronic system design, including running the complete initial microcode load (IML), in the pre-silicon system simulation consumes time, such as weeks, even if using hardware accelerators. The initial microcode load refers to the process of loading the very first set of microinstructions into a CPU's control store during the boot sequence thereby providing the basic set of commands needed for the processor to function at a fundamental level and execute further instructions.

In contrast to utilizing a pre-silicon system simulation for testing the initial microcode load (IML), the IML may be tested using a firmware simulator, such as the central electronic complex simulator (CECSIM), which not only reaches the post IML state (completion of the IML load) very quickly (e.g., 5 minutes) but provides data and the state of all microcode components, such as the millicode (a higher level of microcode used to implement part of the instruction set of a computer) and i390 (higher level of firmware that implements functions, such as the channel-subsystem, recovery, and power-on-reset functions). Hence, firmware engineers prefer debugging microcode issues in a microcode simulation environment, such as a firmware simulation environment.

However, hardware engineers prefers debugging hardware issues in a hardware simulation environment as opposed to a firmware simulation environment.

As a result of utilizing different simulation environments to debug firmware (e.g., microcode) and hardware, the time to debug such firmware and hardware becomes excessive. Furthermore, by utilizing different simulation environments to debug firmware (e.g., microcode) and hardware, errors are more likely to occur.

The embodiments of the present disclosure provide a means for testing and debugging firmware and hardware in a collaborative manner that reduces the time to debug both firmware and hardware as well as reduces the number of errors encountered by quickly identifying and fixing issues during the development process thereby preventing bugs from accumulating and causing more complex problems. In one embodiment, a collaborative debug platform is utilized in which a snapshot of an architected state produced by a firmware simulator after executing firmware on the firmware simulator is captured. Such a captured snapshot of the architected state contains register values and memory data from a firmware simulation environment. Furthermore, a hardware simulation model is initialized using the snapshot of the architected state. Additionally, the non-architected state elements of the hardware simulation model are initialized. After such initializations, one or more cycles of hardware execution are simulated on the hardware simulation model. Debugging on hardware facilities of interest (e.g., registers, memory, caches, signals, etc.) on the hardware simulation model is then performed. A snapshot and/or traces of states of the hardware facilities of interest produced by the hardware simulation model after performing the debugging are captured. Such a snapshot and/or traces of states of the hardware facilities of interest are then utilized in executing the firmware on the firmware simulator. In this manner, both the firmware and hardware can be tested and debugged in a collaborative manner which reduces the time to debug both firmware and hardware as well as reduces the number of errors encountered by quickly identifying and fixing issues during the development process thereby preventing bugs from accumulating and causing more complex problems. A further description of these and other features will be provided below.

In the following description, numerous specific details are set forth to provide a thorough understanding of the present disclosure. However, it will be apparent to those skilled in the art that the present disclosure may be practiced without such specific details. In other instances, well-known circuits have been shown in block diagram form in order not to obscure the present disclosure in unnecessary detail. For the most part, details considering timing considerations and the like have been omitted inasmuch as such details are not necessary to obtain a complete understanding of the present disclosure and are within the skills of persons of ordinary skill in the relevant art.

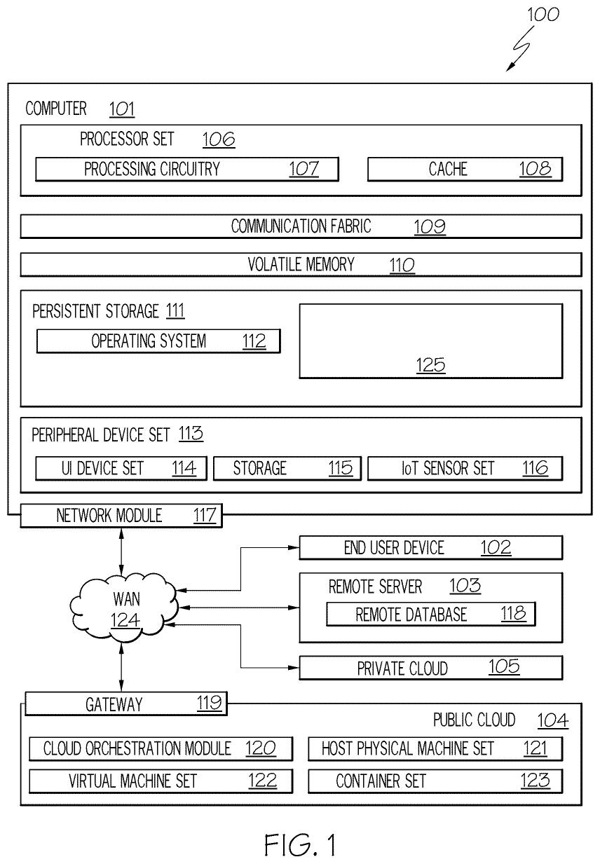

Referring now to the Figures in detail, FIG. 1 illustrates an embodiment of the present disclosure of a computing environment 100 for practicing the principles of the present disclosure.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code (stored in block 125) involved in performing the inventive methods, such as testing and debugging both the firmware and hardware in a collaborative manner. In addition to block 125, computing environment 100 includes, for example, computer 101, network 124, such as a wide area network (WAN), end user device (EUD) 102, remote server 103, public cloud 104, and private cloud 105. In this embodiment, computer 101 includes processor set 106 (including processing circuitry 107 and cache 108), communication fabric 109, volatile memory 110, persistent storage 111 (including operating system 112 and block 125, as identified above), peripheral device set 113 (including user interface (UI) device set 114, storage 115, and Internet of Things (IoT) sensor set 116), and network module 117. Remote server 103 includes remote database 118. Public cloud 104 includes gateway 119, cloud orchestration module 120, host physical machine set 121, virtual machine set 122, and container set 123.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 118. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 106 includes one, or more, computer processors of any type now known or to be developed in the future. Processing circuitry 107 may be distributed over multiple packages, for example, multiple, coordinated integrated circuit chips. Processing circuitry 107 may implement multiple processor threads and/or multiple processor cores. Cache 108 is memory that is located in the processor chip package(s) and is typically used for data or code that should be available for rapid access by the threads or cores running on processor set 106. Cache memories are typically organized into multiple levels depending upon relative proximity to the processing circuitry. Alternatively, some, or all, of the cache for the processor set may be located “off chip.” In some computing environments, processor set 106 may be designed for working with qubits and performing quantum computing.

Computer readable program instructions are typically loaded onto computer 101 to cause a series of operational steps to be performed by processor set 106 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 108 and the other storage media discussed below. The program instructions, and associated data, are accessed by processor set 106 to control and direct performance of the inventive methods. In computing environment 100, at least some of the instructions for performing the inventive methods may be stored in block 125 in persistent storage 111.

Communication fabric 109 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 110 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 110 is located in a single package and is internal to computer 101, but, alternatively or additionally, the volatile memory may be distributed over multiple packages and/or located externally with respect to computer 101.

Persistent Storage 111 is any form of non-volatile storage for computers that is now known or to be developed in the future. The non-volatility of this storage means that the stored data is maintained regardless of whether power is being supplied to computer 101 and/or directly to persistent storage 111. Persistent storage 111 may be a read only memory (ROM), but typically at least a portion of the persistent storage allows writing of data, deletion of data and re-writing of data. Some familiar forms of persistent storage include magnetic disks and solid state storage devices. Operating system 112 may take several forms, such as various known proprietary operating systems or open source Portable Operating System Interface type operating systems that employ a kernel. The code included in block 125 typically includes at least some of the computer code involved in performing the inventive methods.

Peripheral device set 113 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 114 may include components such as a display screen, speaker, microphone, wearable devices (such as goggles and smart watches), keyboard, mouse, printer, touchpad, game controllers, and haptic devices. Storage 115 is external storage, such as an external hard drive, or insertable storage, such as an SD card. Storage 115 may be persistent and/or volatile. In some embodiments, storage 115 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 116 is made up of sensors that can be used in Internet of Things applications. For example, one sensor may be a thermometer and another sensor may be a motion detector.

Network module 117 is the collection of computer software, hardware, and firmware that allows computer 101 to communicate with other computers through WAN 124. Network module 117 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 117 are performed on the same physical hardware device. In other embodiments (for example, embodiments that utilize software-defined networking (SDN)), the control functions and the forwarding functions of network module 117 are performed on physically separate devices, such that the control functions manage several different network hardware devices. Computer readable program instructions for performing the inventive methods can typically be downloaded to computer 101 from an external computer or external storage device through a network adapter card or network interface included in network module 117.

WAN 124 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 102 is any computer system that is used and controlled by an end user (for example, a customer of an enterprise that operates computer 101), and may take any of the forms discussed above in connection with computer 101. EUD 102 typically receives helpful and useful data from the operations of computer 101. For example, in a hypothetical case where computer 101 is designed to provide a recommendation to an end user, this recommendation would typically be communicated from network module 117 of computer 101 through WAN 124 to EUD 102. In this way, EUD 102 can display, or otherwise present, the recommendation to an end user. In some embodiments, EUD 102 may be a client device, such as thin client, heavy client, mainframe computer, desktop computer and so on.

Remote server 103 is any computer system that serves at least some data and/or functionality to computer 101. Remote server 103 may be controlled and used by the same entity that operates computer 101. Remote server 103 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 118 of remote server 103.

Public cloud 104 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 104 is performed by the computer hardware and/or software of cloud orchestration module 120. The computing resources provided by public cloud 104 are typically implemented by virtual computing environments that run on various computers making up the computers of host physical machine set 121, which is the universe of physical computers in and/or available to public cloud 104. The virtual computing environments (VCEs) typically take the form of virtual machines from virtual machine set 122 and/or containers from container set 123. It is understood that these VCEs may be stored as images and may be transferred among and between the various physical machine hosts, either as images or after instantiation of the VCE. Cloud orchestration module 120 manages the transfer and storage of images, deploys new instantiations of VCEs and manages active instantiations of VCE deployments. Gateway 119 is the collection of computer software, hardware, and firmware that allows public cloud 104 to communicate through WAN 124.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 105 is similar to public cloud 104, except that the computing resources are only available for use by a single enterprise. While private cloud 105 is depicted as being in communication with WAN 124 in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 104 and private cloud 105 are both part of a larger hybrid cloud.

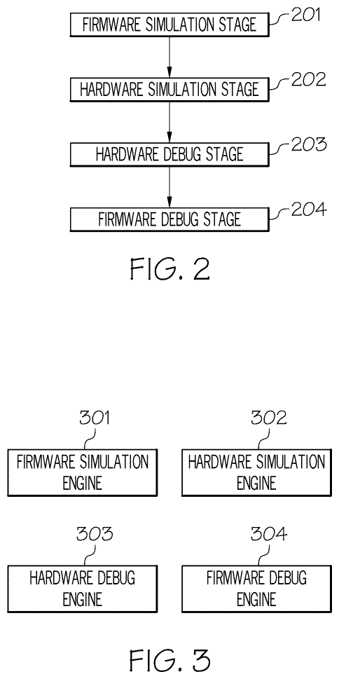

Block 125 further includes the software components discussed herein in connection with FIGS. 2-3 and 4A-4B to test and debug both the firmware and hardware in a collaborative manner. In one embodiment, such components may be implemented in hardware. The functions discussed above performed by such components are not generic computer functions. As a result, computer 101 is a particular machine that is the result of implementing specific, non-generic computer functions.

In one embodiment, the functionality of such software components of computer 101, including the functionality for testing and debugging both the firmware and hardware in a collaborative manner, may be embodied in an application specific integrated circuit.

In one embodiment, computer 101 includes a collaborative debug platform for testing and debugging firmware and hardware in a collaborative manner in various stages as illustrated in FIG. 2.

Referring to FIG. 2, FIG. 2 illustrates the stages performed in testing and debugging firmware and hardware in a collaborative manner in accordance with an embodiment of the present disclosure.

As shown in FIG. 2, in one embodiment, the collaborative debug platform for testing and debugging firmware and hardware in a collaborative manner begins with the firmware simulation stage 201. “Firmware simulation stage 201,” as used herein, refers to the phase where software tools are utilized to test firmware code (e.g., microcode, such as the initial microcode load) without needing a physical device thereby simulating how the firmware would function on the actual hardware before deployment to identify potential issues early in the development cycle.

In one embodiment, a snapshot of the architected state produced during firmware simulation stage 201 is captured. In one embodiment, such a snapshot of the architected state contains register values and memory data from the firmware simulation environment. A “snapshot,” as used herein, refers to the state of the system at a particular point in time.

Upon completion of firmware simulation stage 201, the process in testing and debugging firmware and hardware in a collaborative manner moves to the hardware simulation stage 202. “Hardware simulation stage 202,” as used herein, refers to the phase in the design process where a virtual model of a hardware circuit or system is created and tested using specialized software to verify its functionality and identify potential issues before physically building the hardware.

In one embodiment, during hardware simulation stage 202, a hardware simulation model is initialized using the snapshot of the architected state. Furthermore, in one embodiment, during hardware simulation stage 202, non-architected state elements of the hardware simulation model are initialized, such as by using a hardware simulator supervisor program.

Furthermore, in one embodiment, during hardware simulation stage 202, one or more cycles of hardware execution on the hardware simulation model are simulated.

Upon completion of hardware simulation stage 202, debugging of designated hardware facilities of interest (e.g., registers, memory, caches, signals, etc.) on the hardware simulation model is performed in hardware debug stage 203. Hardware debug stage 203, as used herein, refers to the phase in the development process in identifying issues within the physical hardware components of the system to verify that the hardware is functioning as designed.

In one embodiment, during hardware debug stage 203, a snapshot and/or traces of states of the hardware facilities of interest produced by the hardware simulation model are captured.

Upon completion of hardware debug stage 203, the firmware is then executed on the firmware simulator using such a snapshot and/or traces of states of the hardware facilities of interest during firmware debug stage 204. Firmware debug stage 204, as used herein, refers to the development phase where errors (bugs) within the firmware code of an embedded system are identified to be corrected using specialized tools and techniques.

A further discussion regarding the functionality of each of the stages is provided below in connection with the discussion of the components used by computer 101 to test and debug firmware and hardware in a collaborative manner.

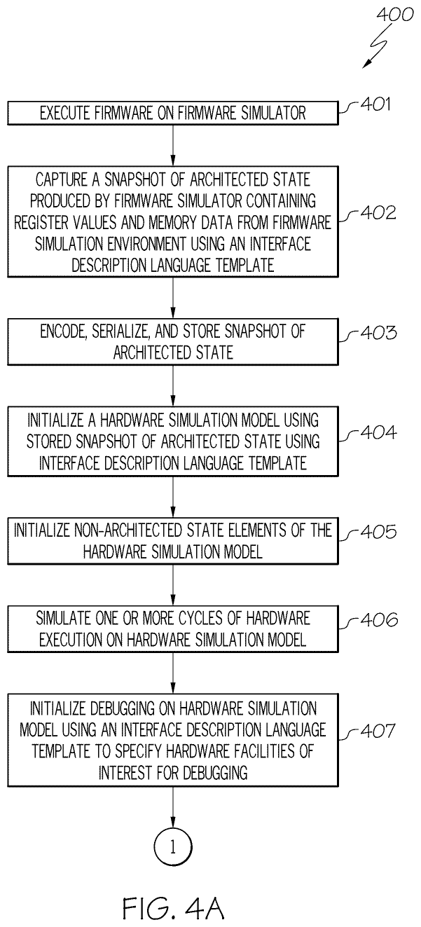

FIG. 3 is a diagram of the software components used by computer 101 to test and debug firmware and hardware in a collaborative manner in accordance with an embodiment of the present disclosure.

Referring to FIG. 3, in conjunction with FIGS. 1-2, computer 101 includes firmware simulation engine 301 configured to execute firmware on a firmware simulator during firmware simulation stage 201. Firmware, as used herein, refers to software that is permanently stored in hardware devices. A firmware simulator, as used herein, refers to software that replicates the behavior of a device's hardware environment thereby allowing firmware code to be tested and debugged without needing the actual physical device. That is, the firmware simulator enables simulating how the firmware would function on the real hardware, including its interactions with various peripherals and components. An example of a firmware simulator includes the central electronic complex simulator (CECSIM).

In one embodiment, the firmware simulator corresponds to an ISA (instruction set architecture)-level simulator which models the instruction set architecture of a computer's processor. In one embodiment, the firmware simulator corresponds to a microcode-level simulator. A microcode-level simulator, as used herein, refers to a software tool used to test and debug the low-level microcode instructions (set of low-level, hardware-specific instructions that act as a bridge between the processor's machine code instructions and the actual circuitry) of a processor.

Furthermore, in one embodiment, firmware simulation engine 301 is configured to capture a snapshot of an architected state produced by the firmware simulator after executing firmware on the firmware simulator during firmware simulation stage 201. As previously discussed, a snapshot, as used herein, refers to the state of the system at a particular point in time. In one embodiment, such a captured snapshot of the architected state contains register values and memory data from the firmware simulation environment.

In one embodiment, firmware simulation engine 301 uses an interface description language template to capture the snapshot of the architected state produced by the firmware simulator after executing firmware on the firmware simulator during firmware simulation stage 201. An interface description language, as used herein, is a specialized language used to define the structure and functionality of a software component's interface in a way that is independent of the programming language. An interface description language template, as used herein, refers to a pre-defined structure or format used to document the details of a software interface, such as in a language-agnostic manner, specifying the available functions, data types, and parameters that a component or system can interact with.

In one embodiment, the interface description language template specifies the architected registers and memory used by the software.

In one embodiment, an example of such an interface description language corresponds to the protocol buffer (also referred to as “protobuf”), which is a data format used to serialize structured data.

In one embodiment, firmware simulation engine 301 examines the architected state produced by the firmware simulator after executing firmware on the firmware simulator by adding probes to registers, memory addresses, etc. to examine their values as the simulation progresses. In one embodiment, firmware simulation engine 301 uses a register window to examine the architected state produced by the firmware simulator during the simulation run, where the register window displays the current values of the architected registers and memory within the design at any given point in the simulation. In another embodiment, firmware simulation engine 301 sets breakpoints at specific points in the simulation to pause execution and examine the current state of the design, including registers and memory contents.

In one embodiment, firmware simulation engine 301 encodes, serializes, and stores the snapshot of the architected state produced by the firmware simulator during firmware simulation stage 201. In one embodiment, encoding involves the process of converting the current values stored in registers and memory locations into a format that can be easily represented and manipulated to capture the exact state of the system at a particular point in time. In one embodiment, serializing involves translating a data structure or object, including the encoded values stored in registers and memory locations, into a format that can be stored. In one embodiment, the serialized snapshot of the architected state is stored in a storage device (e.g., storage device 111, 115) of computer 101.

Firmware simulation engine 301 utilizes various software tools to perform the functions discussed above, including, but not limited to, QEMU®, P2IM, Laelaps®, JetSet, Fuzzware, FirmWire, etc.

Computer 101 further includes hardware simulation engine 302 configured to initialize a hardware simulation model using the stored snapshot of the architected state using an interface description language template during hardware simulation stage 202. In one embodiment, such an interface description language template corresponds to the same interface description language template used to specify the architected registers and memory used by the software. By initializing the hardware simulation model using the captured snapshot of the architected state produced by the firmware simulator, the architected state produced by the firmware simulator is transferred to the hardware simulation environment.

In one embodiment, the snapshot of the architected state is used to drive the hardware simulation model reusing the system simulation verification drivers. That is, the snapshot of the architected state is used as input to control the behavior of a detailed hardware simulation model using system simulation verification drivers which act as an interface between the high-level design and the detailed hardware simulation. As a result, with the help of such system simulation verification drivers, the components which are not present in the firmware model may be driven to a defined state.

A “hardware simulation model,” as used herein, is a virtual representation of a physical hardware system used to test and analyze its functionality, performance, and reliability before building the actual device.

In one embodiment, hardware simulation engine 302 initializes the hardware simulation model by setting the initial values of all relevant parameters within the model, including state variables, inputs, and configuration settings. In one embodiment, such an initialization involves selecting the appropriate hardware components within the simulation environment defining their initial states and configuring any relevant connections or interactions between them. For example, the voltage levels of the capacitors within the hardware simulation model are assigned initial values.

In one embodiment, hardware simulation engine 302 initializes the non-architected state elements of the hardware simulation model, such as by using a hardware simulator supervisor program, during hardware simulation stage 202. A hardware simulator supervisor program, as used herein, refers to a software application within the hardware simulation environment that controls and manipulates aspects of the hardware simulation by managing the simulation's parameters.

In one embodiment, hardware simulation engine 302 initializes the non-architected state elements of the hardware simulation model by setting the initial values of all relevant parameters for such non-architected state elements (e.g., flags, program counters) within the model. For example, hardware simulation engine 302 sets the initial values of the non-architected state elements of the hardware simulation model, such as the initial values of the program counter (which instruction to execute next), relevant flags (e.g., carry flag), etc. prior to starting the simulation.

In one embodiment, hardware simulation engine 302 initializes the hardware simulation model using the stored snapshot of the architected state and initializes the non-architected state elements of the hardware simulation model so that the simulation will not start with random or undefined states thereby preventing inaccurate results or unexpected behavior in the simulated hardware.

In one embodiment, hardware simulation engine 302 simulates one or more cycles of hardware execution on the hardware simulation model during hardware simulation stage 202.

In one embodiment, hardware simulation engine 302 simulates one or more cycles of hardware execution on the hardware simulation model during hardware simulation stage 202 by running a virtual representation of hardware through a single or multiple clock cycles thereby mimicking how the real hardware behaves by processing data step-by-step within the confines of a program that models the hardware design.

Hardware simulation engine 302 utilizes various software tools to perform the functions discussed above, including, but not limited to, Cadence® Virtuoso®, Synopsys® VCS, Mentor Graphics® Questa®, ModelSim®, Verilog-AMS, SystemVerilog, Matlab® Simulink®, ANSYS®, SPICE® simulators, etc.

In one embodiment, computer 101 includes hardware debug engine 303 configured to initialize debugging on the hardware simulation model during hardware debug stage 203. Debugging, as used herein, refers to identifying and removing errors from computer hardware or software.

In one embodiment, hardware debug engine 303 initializes debugging on the hardware simulation model using an interface description language template to specify hardware facilities of interest for debugging. In one embodiment, such an interface description language template may correspond to a different template than the interface description language template utilized for capturing a snapshot of the architected state produced by the firmware simulator and for initializing the hardware simulation model. The hardware facilities of interest, as used herein, refer to the hardware features, such as the components, speed, and storage capacity, on the hardware simulation model to be debugged. For example, the hardware facilities of interest may correspond to registers, memory, caches, signals, etc.

In one embodiment, hardware debug engine 303 performs debugging on the hardware simulation model during hardware debug stage 203. In one embodiment, such debugging involves debugging of the hardware facilities of interest on the hardware simulation model.

In one embodiment, hardware debug engine 303 uses various simulation tools, such as waveform viewers, breakpoints, signal monitoring, etc. to analyze the behavior of the hardware facilities of interest and identify where the hardware simulation model deviates from the expected functionality.

In one embodiment, hardware debug engine 303 develops a testbench that provides various input stimuli to the hardware simulation model to exercise different functionalities. The hardware simulation model is then executed with the testbench to observe the behavior of the hardware facilities of interest and identify potential issues.

In one embodiment, hardware debug engine 303 utilizes various debugging tools for debugging the hardware facilities of interest. For example, hardware debug engine 303 uses a waveform viewer to visualize the signal changes over time to analyze how signals interact and identify unexpected transitions or glitches. In another example, hardware debug engine 303 uses breakpoints, which correspond to pauses in the simulation at specific points in the code to examine signal values and debug logic flow. In a further example, hardware debug engine 303 uses signal probes, which are added to specific signals within the design to monitor their values during the simulation. Additionally, hardware debug engine 303 adds logging statements to print key signal values at different points in the simulation for analysis.

In one embodiment, hardware debug engine 303 captures a snapshot and/or traces of states of the hardware facilities of interest produced by the hardware simulation model after debugging during hardware debug stage 203.

In one embodiment, hardware debug engine 303 captures the snapshot and/or traces of states of the hardware facilities of interest produced by the hardware simulation model after debugging by examining the output values of the signals within the design at different points in time. In one embodiment, hardware debug engine 303 captures the snapshot and/or traces of states of the hardware facilities of interest produced by the hardware simulation model after debugging by examining the states of the hardware facilities of interest during the simulation run using a dedicated waveform viewer or register window that displays the data changes over time. In this manner, hardware debug engine 303 is able to monitor how the states of the hardware facilities of interest evolve across clock cycles.

For example, hardware debug engine 303 examines the states of the hardware facilities of interest during the simulation run by adding probes to specific signals, registers, cache addresses, etc. to examine their values as the simulation progresses. In one embodiment, hardware debug engine 303 uses a register window to examine the states of the hardware facilities of interest during the simulation run, where the register window displays the current values of the hardware facilities of interest (e.g., registers) within the design at any given point in the simulation. In another embodiment, hardware debug engine 303 sets breakpoints at specific points in the simulation to pause execution and examine the current state of the design, including registers and cache contents.

In one embodiment, hardware debug engine 303 encodes, serializes, and stores the snapshot and/or traces of states of the hardware facilities of interest during hardware debug stage 203. In one embodiment, encoding involves the process of converting the current values stored in the states of the hardware facilities of interest into a format that can be easily represented and manipulated to capture the exact state of the system at a particular point in time. In one embodiment, serializing involves translating a data structure or object, including the encoded values stored in the states of the hardware facilities of interest, into a format that can be stored. In one embodiment, the serialized snapshot and/or traces of states of the hardware facilities of interest are stored in a storage device (e.g., storage device 111, 115) of computer 101.

Hardware debug engine 303 utilizes various software tools to perform the functions discussed above, including, but not limited to, ModelSim®, Icarus Verilog®, Vivado®, Quartus®, JTAG, etc.

Furthermore, computer 101 includes firmware debug engine 304 configured to initialize the firmware simulation model using the stored snapshot and/or traces of states of the hardware facilities of interest during firmware debug stage 204. In one embodiment, such an initialization is performed using the same interface description language template as used for capturing the snapshot of the architected state produced by the firmware simulator.

In one embodiment, firmware debug engine 304 initializes the firmware simulation model using the stored snapshot and/or traces of states of the hardware facilities of interest by specifying the initial conditions in the model's configuration parameters corresponding to the values in the stored snapshot and/or traces of states of the hardware facilities of interest.

Additionally, firmware debug engine 304 executes the firmware on the firmware simulator using the stored snapshot and/or traces of states of the hardware facilities of interest during firmware debug stage 204.

As discussed above, the firmware simulator enables simulating how the firmware would function on the real hardware, including its interactions with various peripherals and components. An example of a firmware simulator includes the central electronic complex simulator (CECSIM).

In one embodiment, the firmware simulator corresponds to an ISA (instruction set architecture)-level simulator which models the instruction set architecture of a computer's processor. In one embodiment, the firmware simulator corresponds to a microcode-level simulator. A microcode-level simulator, as used herein, refers to a software tool used to test and debug the low-level microcode instructions (set of low-level, hardware-specific instructions that act as a bridge between the processor's machine code instructions and the actual circuitry) of a processor.

Firmware debug engine 304 utilizes various software tools to perform the functions discussed above, including, but not limited to, QEMU®, GDB, ARM® Cortex-M simulator, Unicorn, etc.

By executing the firmware on the firmware simulator using the stored snapshot and/or traces of states of the hardware facilities of interest produced by the hardware simulator after debugging, the states of such hardware facilities of interest are transferred to the firmware simulation environment.

In this manner, by transferring the simulation states between the firmware simulation environment and the hardware simulation environment and vice-versa, a platform that tests and debugs both the firmware and hardware in a collaborative manner is achieved. By utilizing such a collaborative platform, the time to debug both the firmware and hardware is reduced and the number of errors encountered is reduced by quickly identifying and fixing issues during the development process thereby preventing bugs from accumulating and causing more complex problems.

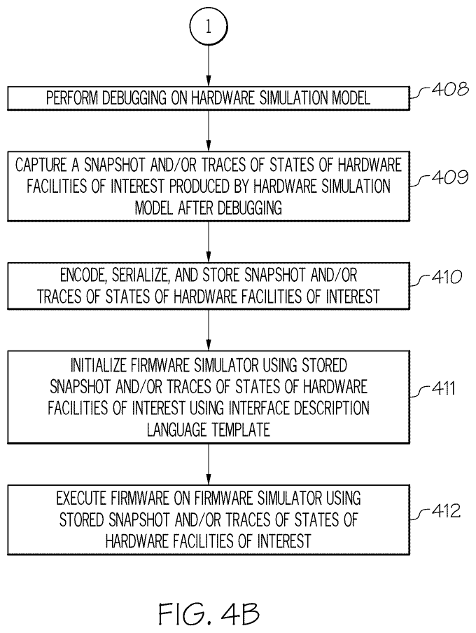

A discussion regarding the method for testing and debugging firmware and hardware in a collaborative manner is provided below in connection with FIGS. 4A-4B.

FIGS. 4A-4B are a flowchart of a method 400 for testing and debugging firmware and hardware in a collaborative manner in accordance with an embodiment of the present disclosure.

Referring to FIG. 4A, in conjunction with FIGS. 1-3, in step 401, firmware simulation engine 301 executes firmware on a firmware simulator during firmware simulation stage 201.

As discussed above, firmware, as used herein, refers to software that is permanently stored in hardware devices. A firmware simulator, as used herein, refers to software that replicates the behavior of a device's hardware environment thereby allowing firmware code to be tested and debugged without needing the actual physical device. That is, the firmware simulator enables simulating how the firmware would function on the real hardware, including its interactions with various peripherals and components. An example of a firmware simulator includes the central electronic complex simulator (CECSIM).

In one embodiment, the firmware simulator corresponds to an ISA (instruction set architecture)-level simulator which models the instruction set architecture of a computer's processor. In one embodiment, the firmware simulator corresponds to a microcode-level simulator. A microcode-level simulator, as used herein, refers to a software tool used to test and debug the low-level microcode instructions (set of low-level, hardware-specific instructions that act as a bridge between the processor's machine code instructions and the actual circuitry) of a processor.

In step 402, firmware simulation engine 301 captures a snapshot of an architected state produced by the firmware simulator after executing firmware on the firmware simulator during firmware simulation stage 201. As previously discussed, a snapshot, as used herein, refers to the state of the system at a particular point in time. In one embodiment, such a captured snapshot of the architected state contains register values and memory data from the firmware simulation environment.

As stated above, in one embodiment, firmware simulation engine 301 uses an interface description language template to capture the snapshot of the architected state produced by the firmware simulator after executing firmware on the firmware simulator during firmware simulation stage 201. An interface description language, as used herein, is a specialized language used to define the structure and functionality of a software component's interface in a way that is independent of the programming language. An interface description language template, as used herein, refers to a pre-defined structure or format used to document the details of a software interface, such as in a language-agnostic manner, specifying the available functions, data types, and parameters that a component or system can interact with.

In one embodiment, the interface description language template specifies the architected registers and memory used by the software.

In one embodiment, an example of such an interface description language corresponds to the protocol buffer (also referred to as “protobuf”), which is a data format used to serialize structured data.

In one embodiment, firmware simulation engine 301 examines the architected state produced by the firmware simulator after executing firmware on the firmware simulator by adding probes to registers, memory addresses, etc. to examine their values as the simulation progresses. In one embodiment, firmware simulation engine 301 uses a register window to examine the architected state produced by the firmware simulator during the simulation run, where the register window displays the current values of the architected registers and memory within the design at any given point in the simulation. In another embodiment, firmware simulation engine 301 sets breakpoints at specific points in the simulation to pause execution and examine the current state of the design, including registers and memory contents.

In step 403, firmware simulation engine 301 encodes, serializes, and stores the snapshot of the architected state produced by the firmware simulator during firmware simulation stage 201.

As discussed above, in one embodiment, encoding involves the process of converting the current values stored in registers and memory locations into a format that can be easily represented and manipulated to capture the exact state of the system at a particular point in time. In one embodiment, serializing involves translating a data structure or object, including the encoded values stored in registers and memory locations, into a format that can be stored. In one embodiment, the serialized snapshot of the architected state is stored in a storage device (e.g., storage device 111, 115) of computer 101.

Firmware simulation engine 301 utilizes various software tools to perform the functions discussed above, including, but not limited to, QEMU®, P2IM, Laelaps®, JetSet, Fuzzware, FirmWire, etc.

In step 404, hardware simulation engine 302 initializes a hardware simulation model using the stored snapshot of the architected state using an interface description language template during hardware simulation stage 202.

As stated above, in one embodiment, such an interface description language template corresponds to the same interface description language template used to specify the architected registers and memory used by the software. By initializing the hardware simulation model using the captured snapshot of the architected state produced by the firmware simulator, the architected state produced by the firmware simulator is transferred to the hardware simulation environment.

In one embodiment, the snapshot of the architected state is used to drive the hardware simulation model reusing the system simulation verification drivers. That is, the snapshot of the architected state is used as input to control the behavior of a detailed hardware simulation model using system simulation verification drivers which act as an interface between the high-level design and the detailed hardware simulation. As a result, with the help of such system simulation verification drivers, the components which are not present in the firmware model may be driven to a defined state.

A “hardware simulation model,” as used herein, is a virtual representation of a physical hardware system used to test and analyze its functionality, performance, and reliability before building the actual device.

In one embodiment, hardware simulation engine 302 initializes the hardware simulation model by setting the initial values of all relevant parameters within the model, including state variables, inputs, and configuration settings. In one embodiment, such an initialization involves selecting the appropriate hardware components within the simulation environment defining their initial states and configuring any relevant connections or interactions between them. For example, the voltage levels of the capacitors within the hardware simulation model are assigned initial values.

In step 405, hardware simulation engine 302 initializes the non-architected state elements of the hardware simulation model, such as by using a hardware simulator supervisor program, during hardware simulation stage 202.

As discussed above, a hardware simulator supervisor program, as used herein, refers to a software application within the hardware simulation environment that controls and manipulates aspects of the hardware simulation by managing the simulation's parameters.

In one embodiment, hardware simulation engine 302 initializes the non-architected state elements of the hardware simulation model by setting the initial values of all relevant parameters for such non-architected state elements (e.g., flags, program counters) within the model. For example, hardware simulation engine 302 sets the initial values of the non-architected state elements of the hardware simulation model, such as the initial values of the program counter (which instruction to execute next), relevant flags (e.g., carry flag), etc. prior to starting the simulation.

In one embodiment, hardware simulation engine 302 initializes the hardware simulation model using the stored snapshot of the architected state and initializes the non-architected state elements of the hardware simulation model so that the simulation will not start with random or undefined states thereby preventing inaccurate results or unexpected behavior in the simulated hardware.

In step 406, hardware simulation engine 302 simulates one or more cycles of hardware execution on the hardware simulation model during hardware simulation stage 202.

As stated above, in one embodiment, hardware simulation engine 302 simulates one or more cycles of hardware execution on the hardware simulation model during hardware simulation stage 202 by running a virtual representation of hardware through a single or multiple clock cycles thereby mimicking how the real hardware behaves by processing data step-by-step within the confines of a program that models the hardware design.

Hardware simulation engine 302 utilizes various software tools to perform the functions discussed above, including, but not limited to, Cadence® Virtuoso®, Synopsys® VCS, Mentor Graphics® Questa®, ModelSim®, Verilog-AMS, SystemVerilog, Matlab® Simulink®, ANSYS®, SPICE® simulators, etc.

In step 407, hardware debug engine 303 initializes the debugging on the hardware simulation model during hardware debug stage 203. Debugging, as used herein, refers to identifying and removing errors from computer hardware or software.

As discussed above, in one embodiment, hardware debug engine 303 initializes debugging on the hardware simulation model using an interface description language template to specify hardware facilities of interest for debugging. In one embodiment, such an interface description language template may correspond to a different template than the interface description language template utilized for capturing a snapshot of the architected state produced by the firmware simulator and for initializing the hardware simulation model. The hardware facilities of interest, as used herein, refer to the hardware features, such as the components, speed, and storage capacity, on the hardware simulation model to be debugged. For example, the hardware facilities of interest may correspond to registers, memory, caches, signals, etc.

Referring now to FIG. 4B, in conjunction with FIGS. 1-3, in step 408, hardware debug engine 303 performs debugging on the hardware simulation model during hardware debug stage 203. In one embodiment, such debugging involves debugging of the hardware facilities of interest on the hardware simulation model.

As stated above, in one embodiment, hardware debug engine 303 uses various simulation tools, such as waveform viewers, breakpoints, signal monitoring, etc. to analyze the behavior of the hardware facilities of interest and identify where the hardware simulation model deviates from the expected functionality.

In one embodiment, hardware debug engine 303 develops a testbench that provides various input stimuli to the hardware simulation model to exercise different functionalities. The hardware simulation model is then executed with the testbench to observe the behavior of the hardware facilities of interest and identify potential issues.

In one embodiment, hardware debug engine 303 utilizes various debugging tools for debugging the hardware facilities of interest. For example, hardware debug engine 303 uses a waveform viewer to visualize the signal changes over time to analyze how signals interact and identify unexpected transitions or glitches. In another example, hardware debug engine 303 uses breakpoints, which correspond to pauses in the simulation at specific points in the code to examine signal values and debug logic flow. In a further example, hardware debug engine 303 uses signal probes, which are added to specific signals within the design to monitor their values during the simulation. Additionally, hardware debug engine 303 adds logging statements to print key signal values at different points in the simulation for analysis.

In step 409, hardware debug engine 303 captures a snapshot and/or traces of states of the hardware facilities of interest produced by the hardware simulation model after debugging during hardware debug stage 203.

As discussed above, in one embodiment, hardware debug engine 303 captures the snapshot and/or traces of states of the hardware facilities of interest produced by the hardware simulation model after debugging by examining the output values of the signals within the design at different points in time. In one embodiment, hardware debug engine 303 captures the snapshot and/or traces of states of the hardware facilities of interest produced by the hardware simulation model after debugging by examining the states of the hardware facilities of interest during the simulation run using a dedicated waveform viewer or register window that displays the data changes over time. In this manner, hardware debug engine 303 is able to monitor how the states of the hardware facilities of interest evolve across clock cycles.

For example, hardware debug engine 303 examines the states of the hardware facilities of interest during the simulation run by adding probes to specific signals, registers, cache addresses, etc. to examine their values as the simulation progresses. In one embodiment, hardware debug engine 303 uses a register window to examine the states of the hardware facilities of interest during the simulation run, where the register window displays the current values of the hardware facilities of interest (e.g., registers) within the design at any given point in the simulation. In another embodiment, hardware debug engine 303 sets breakpoints at specific points in the simulation to pause execution and examine the current state of the design, including registers and cache contents.

In step 410, hardware debug engine 303 encodes, serializes, and stores the snapshot and/or traces of states of the hardware facilities of interest during hardware debug stage 203.

As stated above, in one embodiment, encoding involves the process of converting the current values stored in the states of the hardware facilities of interest into a format that can be easily represented and manipulated to capture the exact state of the system at a particular point in time. In one embodiment, serializing involves translating a data structure or object, including the encoded values stored in the states of the hardware facilities of interest, into a format that can be stored. In one embodiment, the serialized snapshot and/or traces of states of the hardware facilities of interest are stored in a storage device (e.g., storage device 111, 115) of computer 101.

Hardware debug engine 303 utilizes various software tools to perform the functions discussed above, including, but not limited to, ModelSim®, Icarus Verilog®, Vivado®, Quartus®, JTAG, etc.

In step 411, firmware debug engine 304 initializes the firmware simulator using the stored snapshot and/or traces of states of the hardware facilities of interest during firmware debug stage 204. In one embodiment, such an initialization is performed using the same interface description language template as used for capturing the snapshot of the architected state produced by the firmware simulator.

As discussed above, in one embodiment, firmware debug engine 304 initializes the firmware simulation model using the stored snapshot and/or traces of states of the hardware facilities of interest by specifying the initial conditions in the model's configuration parameters corresponding to the values in the stored snapshot and/or traces of states of the hardware facilities of interest.

In step 412, firmware debug engine 304 executes the firmware on the firmware simulator using the stored snapshot and/or traces of states of the hardware facilities of interest during firmware debug stage 204.

As discussed above, the firmware simulator enables simulating how the firmware would function on the real hardware, including its interactions with various peripherals and components. An example of a firmware simulator includes the central electronic complex simulator (CECSIM).

In one embodiment, the firmware simulator corresponds to an ISA (instruction set architecture)-level simulator which models the instruction set architecture of a computer's processor. In one embodiment, the firmware simulator corresponds to a microcode-level simulator.

Firmware debug engine 304 utilizes various software tools to perform the functions discussed above, including, but not limited to, QEMU®, GDB, ARM® Cortex-M simulator, Unicorn, etc.

By executing the firmware on the firmware simulator using the stored snapshot and/or traces of states of the hardware facilities of interest produced by the hardware simulator after debugging, the states of such hardware facilities of interest are transferred to the firmware simulation environment.

In this manner, by transferring the simulation states between the firmware simulation environment and the hardware simulation environment and vice-versa, a platform that tests and debugs both the firmware and hardware in a collaborative manner is achieved. By utilizing such a collaborative platform, the time to debug both the firmware and hardware is reduced and the number of errors encountered is reduced by quickly identifying and fixing issues during the development process thereby preventing bugs from accumulating and causing more complex problems.

Furthermore, the principles of the present disclosure improve the technology or technical field involving testing and debugging in the context of firmware and hardware.

As discussed above, in the context of firmware and hardware, “testing” refers to verifying that the firmware (e.g., the software embedded within a hardware device) or hardware (e.g., hardware device) functions correctly by running it through various scenarios to identify potential issues while “debugging” refers to the process of pinpointing and fixing specific errors or bugs found during testing. Such testing and debugging may involve pre-silicon system simulation, which refers to the process of testing and verifying the functionality of a complete electronic system design using a computer simulation before the actual physical hardware (“silicon”) is manufactured. For example, pre-silicon system simulation is performed to identify and fix potential design flaws in a complex system, such as an integrated circuit (IC) system, before the physical chip is manufactured allowing for earlier bug detection, faster development cycles, and reduced costs by mitigating the need for costly silicon re-spins later in the process. By simulating the system behavior before silicon is fabricated, design issues can be identified and corrected early in the design process, preventing potential problems that could arise once the chip is physically built. That is, identifying and fixing bugs early in the design process significantly reduces the overall development time by minimizing the need for post-silicon debugging and rework. However, testing and verifying the functionality of a complete electronic system design, including running the complete initial microcode load (IML), in the pre-silicon system simulation consumes time, such as weeks, even if using hardware accelerators. The initial microcode load refers to the process of loading the very first set of microinstructions into a CPU's control store during the boot sequence thereby providing the basic set of commands needed for the processor to function at a fundamental level and execute further instructions. In contrast to utilizing a pre-silicon system simulation for testing the initial microcode load (IML), the IML may be tested using a firmware simulator, such as the central electronic complex simulator (CECSIM), which not only reaches the post IML state (completion of the IML load) very quickly (e.g., 5 minutes) but provides data and the state of all microcode components, such as the millicode (a higher level of microcode used to implement part of the instruction set of a computer) and i390 (higher level of firmware that implements functions, such as the channel-subsystem, recovery, and power-on-reset functions). Hence, firmware engineers prefer debugging microcode issues in a microcode simulation environment, such as a firmware simulation environment. However, hardware engineers prefers debugging hardware issues in a hardware simulation environment as opposed to a firmware simulation environment. As a result of utilizing different simulation environments to debug firmware (e.g., microcode) and hardware, the time to debug such firmware and hardware becomes excessive. Furthermore, by utilizing different simulation environments to debug firmware (e.g., microcode) and hardware, errors are more likely to occur.

Embodiments of the present disclosure improve such technology by utilizing a collaborative debug platform in which a snapshot of an architected state produced by a firmware simulator after executing firmware on the firmware simulator is captured. Such a captured snapshot of the architected state contains register values and memory data from a firmware simulation environment. Furthermore, a hardware simulation model is initialized using the snapshot of the architected state. Additionally, the non-architected state elements of the hardware simulation model are initialized. After such initializations, one or more cycles of hardware execution are simulated on the hardware simulation model. Debugging on hardware facilities of interest (e.g., registers, memory, caches, signals, etc.) on the hardware simulation model is then performed. A snapshot and/or traces of states of the hardware facilities of interest produced by the hardware simulation model after performing the debugging are captured. Such a snapshot and/or traces of states of the hardware facilities of interest are then utilized in executing the firmware on the firmware simulator. In this manner, both the firmware and hardware can be tested and debugged in a collaborative manner which reduces the time to debug both firmware and hardware as well as reduces the number of errors encountered by quickly identifying and fixing issues during the development process thereby preventing bugs from accumulating and causing more complex problems. Furthermore, in this manner, there is an improvement in the technical field involving testing and debugging in the context of firmware and hardware.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A computer-implemented method for testing and debugging firmware and hardware, the method comprising:
executing firmware on a firmware simulator;
capturing a snapshot of an architected state produced by said firmware simulator after executing said firmware on said firmware simulator;
initializing a hardware simulation model using said snapshot of said architected state;
simulating one or more cycles of hardware execution on said hardware simulation model after said initialization of said hardware simulation model;
performing debugging of hardware facilities of interest on said hardware simulation model after said simulation;
capturing one or more of a snapshot and traces of states of said hardware facilities of interest produced by said hardware simulation model after performing said debugging; and
executing said firmware on said firmware simulator using said one or more of said snapshot and said traces of states of said hardware facilities of interest.

2. The method as recited in claim 1, wherein said captured snapshot of said architected state produced by said firmware simulator contains register values and memory data from a firmware simulation environment, wherein said snapshot of said architected state is captured using an interface description language template.

3. The method as recited in claim 2 further comprising:
encoding, serializing, and storing said snapshot of said architected state.

4. The method as recited in claim 2 further comprising:
initializing said hardware simulation model using said snapshot of said architected state using said interface description language template.

5. The method as recited in claim 2 further comprising:
initializing debugging on said hardware simulation model using a second interface description language template to specify said hardware facilities of interest for debugging.

6. The method as recited in claim 1 further comprising:
encoding, serializing, and storing said one or more of said snapshot and said traces of states of said hardware facilities of interest.

7. The method as recited in claim 6 further comprising:
initializing said firmware simulator using one or more of said stored snapshot and said stored traces of states of said hardware facilities of interest using an interface description language template.

8. The method as recited in claim 1 further comprising:
initializing non-architected state elements of said hardware simulation model; and
simulating said one or more cycles of hardware execution on said hardware simulation model after said initialization of said hardware simulation model and said initialization of said non-architected state elements of said hardware simulation model.

9. A computer program product for testing and debugging firmware and hardware, the computer program product comprising one or more computer readable storage mediums having program code embodied therewith, the program code comprising programming instructions for:
executing firmware on a firmware simulator;
capturing a snapshot of an architected state produced by said firmware simulator after executing said firmware on said firmware simulator;
initializing a hardware simulation model using said snapshot of said architected state;
simulating one or more cycles of hardware execution on said hardware simulation model after said initialization of said hardware simulation model;
performing debugging of hardware facilities of interest on said hardware simulation model after said simulation;
capturing one or more of a snapshot and traces of states of said hardware facilities of interest produced by said hardware simulation model after performing said debugging; and
executing said firmware on said firmware simulator using said one or more of said snapshot and said traces of states of said hardware facilities of interest.

10. The computer program product as recited in claim 9, wherein said captured snapshot of said architected state produced by said firmware simulator contains register values and memory data from a firmware simulation environment, wherein said snapshot of said architected state is captured using an interface description language template.

11. The computer program product as recited in claim 10, wherein the program code further comprises the programming instructions for:
encoding, serializing, and storing said snapshot of said architected state.

12. The computer program product as recited in claim 10, wherein the program code further comprises the programming instructions for:
initializing said hardware simulation model using said snapshot of said architected state using said interface description language template.

13. The computer program product as recited in claim 10, wherein the program code further comprises the programming instructions for:
initializing debugging on said hardware simulation model using a second interface description language template to specify said hardware facilities of interest for debugging.

14. The computer program product as recited in claim 9, wherein the program code further comprises the programming instructions for:
encoding, serializing, and storing said one or more of said snapshot and said traces of states of said hardware facilities of interest.

15. The computer program product as recited in claim 14, wherein the program code further comprises the programming instructions for:
initializing said firmware simulator using one or more of said stored snapshot and said stored traces of states of said hardware facilities of interest using an interface description language template.

16. The computer program product as recited in claim 9, wherein the program code further comprises the programming instructions for:
initializing non-architected state elements of said hardware simulation model; and
simulating said one or more cycles of hardware execution on said hardware simulation model after said initialization of said hardware simulation model and said initialization of said non-architected state elements of said hardware simulation model.

17. A system, comprising:
a memory for storing a computer program for testing and debugging firmware and hardware; and
a processor connected to said memory, wherein said processor is configured to execute program instructions of the computer program comprising:
executing firmware on a firmware simulator;
capturing a snapshot of an architected state produced by said firmware simulator after executing said firmware on said firmware simulator;
initializing a hardware simulation model using said snapshot of said architected state;
simulating one or more cycles of hardware execution on said hardware simulation model after said initialization of said hardware simulation model;
performing debugging of hardware facilities of interest on said hardware simulation model after said simulation;
capturing one or more of a snapshot and traces of states of said hardware facilities of interest produced by said hardware simulation model after performing said debugging; and
executing said firmware on said firmware simulator using said one or more of said snapshot and said traces of states of said hardware facilities of interest.

18. The system as recited in claim 17, wherein said captured snapshot of said architected state produced by said firmware simulator contains register values and memory data from a firmware simulation environment, wherein said snapshot of said architected state is captured using an interface description language template.

19. The system as recited in claim 18, wherein the program instructions of the computer program further comprise:
encoding, serializing, and storing said snapshot of said architected state.

20. The system as recited in claim 18, wherein the program instructions of the computer program further comprise:
initializing said hardware simulation model using said snapshot of said architected state using said interface description language template.
